(19) United States
(12) Patent Application Publication
(10) Pub. No.: US 2021/0288612 A1
(43) Pub. Date: Sep. 16, 2021

(54) Bias Compensation Circuit and Amplifying Module

(71) Applicant: WIN Semiconductors Corp., Tao Yuan City (TW)

(72) Inventors: Po-Kie Tseng, Taoyuan City (TW); Chih-Wen Huang, Taoyuan City (TW); Jui-Chieh Chiu, Taoyuan City (TW); Shao-Cheng Hsiao, Taoyuan City (TW)

(21) Appl. No.: 16/816,277

(22) Filed: Mar. 12, 2020

(51) Int. Cl. H03F 1/02; H03F 3/213

(52) U.S. Cl. CPC H03F 1/0211; H03F 2200/129; H03F 2200/451; H03F 3/213

(57) ABSTRACT

A bias compensation circuit, coupled to an amplifying circuit, is disclosed. The bias compensation circuit comprises a transistor, comprising a first terminal, a second terminal and a control terminal; a first feedback transistor, comprising a control terminal, coupled to the first terminal of the transistor; a first terminal, coupled to the control terminal of the transistor; and a second terminal; and a second feedback transistor, comprising a control terminal, coupled to the first terminal of the transistor; a first terminal, coupled to the amplifying circuit; and a second terminal; and a first resistor, comprising a first terminal, coupled to the first terminal of the transistor; and a second terminal, configured to receive a first voltage.

### BACKGROUND OF THE INVENTION

### 1. Field of the Invention

The present application relates to a bias compensation circuit and an amplifying module, and more particularly, to a bias compensation circuit and an amplifying module capable of providing a stable biased current.

### 2. Description of the Prior Art

As a demand of 5G communication systems grows, millimeter wave technology is important in commercial consumer electronics. The good characteristics of GaAs (gallium arsenide) at high/radio frequencies have been widely used in the millimeter wave field. In practice, for mass production, the requirement of stability and invariability of turn on voltage of fabricated transistors after fabrication process or under various temperatures is an important issue.

In many applications of pHEMT, a bias circuit is required to compensate temperature and process variations and maintain stable characteristics. In the art, operational amplifiers or current sources are used to perform the compensation. The operational amplifier or current source may have finer control. However, combining operational amplifier or current source may require additional CMOS or bipolar process, which sacrifices the production cost and a degree of integration.

Therefore, it is necessary to improve the prior art.

### SUMMARY OF THE INVENTION

It is therefore a primary objective of the present application to provide a bias compensation circuit and an amplifying module capable of providing a stable biased current, to improve over disadvantages of the prior art.

An embodiment of the present application discloses a bias compensation circuit coupled to an amplifying circuit. The bias compensation circuit comprises a transistor, comprising a first terminal, a second terminal and a control terminal; a first feedback transistor, comprising a control terminal, coupled to the first terminal of the transistor; a first terminal, coupled to the control terminal of the transistor; and a second terminal; and a second feedback transistor, comprising a control terminal, coupled to the first terminal of the transistor; a first terminal, coupled to the amplifying circuit; and a second terminal; and a first resistor, comprising a first terminal, coupled to the first terminal of the transistor; and a second terminal, configured to receive a first voltage.

An embodiment of the present application further discloses an amplifying module. The amplifying module comprises an amplifying circuit; and a bias compensation circuit, coupled to the amplifying circuit, the bias compensation circuit comprising a transistor, comprising a first terminal, a second terminal and a control terminal; a first feedback transistor, comprising a control terminal, coupled to the first terminal of the transistor; a first terminal, coupled to the control terminal of the transistor; and a second terminal; and a second feedback transistor, comprising a control terminal, coupled to the first terminal of the transistor; a first terminal, coupled to the amplifying circuit; and a second terminal; and a first resistor, comprising a first terminal, coupled to the first terminal of the transistor; and a second terminal, configured to receive a first voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of an amplifying module according to an embodiment of the present application.

FIG. 2 is a schematic diagram of currents of the amplifying module of under various turn on voltages.

FIG. 3 is a schematic diagram of currents of the amplifying module of under various temperatures.

### DETAILED DESCRIPTION

In the present application, a control terminal of a transistor is referred to a gate of the transistor, when the transistor is an FET (Field Effect Transistor) or a (p)HEMT ((Pseudomorphic) High Electron Mobility Transistor), or referred to a base of the transistor, when the transistor is a BJT (Bipolar Junction Transistor) or an HBT (Heterojunction Bipolar Transistor). A terminal, either a first terminal or a second terminal, of a transistor is referred to a source or a drain of the transistor, when the transistor is an FET or a (p)HEMT, or referred to an emitter or collector of the transistor, when the transistor is a BJT or an HBT. For illustrative purpose, the following description takes N-type (p)HEMT or FET as an example, which is not limited thereto.

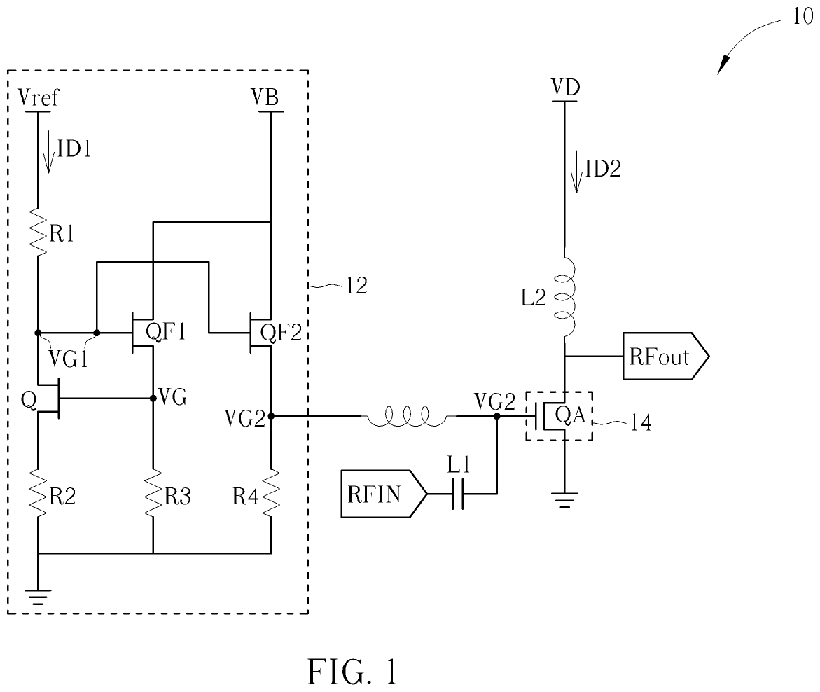

FIG. 1 is a schematic diagram of an amplifying module 10 according to an embodiment of the present application. The amplifying module 10 comprises a bias compensation circuit 12 and an amplifying circuit 14. In the embodiment illustrated in FIG. 1, the amplifying circuit 14 comprises an amplifying transistor QA.

The amplifying module 10 may be formed within a die. In an embodiment, the die may be a GaAs (Gallium Arsenide) die, which is not limited thereto. The amplifying module 10 may be fabricated by a pHEMT process, which is not limited thereto. Note that, the turn on voltage Vto and the threshold voltage Vₜₕ of the transistor(s) are used interchangeably in the present application.

The bias compensation circuit 12 comprises a transistor Q, feedback transistors QF1, QF2, and resistors R1-R4. In the embodiment illustrated in FIG. 1, gates of the feedback transistors QF1, QF2 are coupled to a drain of the transistor Q. Drains of the feedback transistors QF1, QF2 receive a voltage VB. Sources of the transistor Q and the feedback transistors QF1, QF2 are coupled to a ground via the resistors R2-R4, respectively. A drain of the transistor Q and the gates of the feedback transistors QF1, QF2 are coupled to a first terminal of the resistor R1. A second terminal of the resistor R1 receives a voltage Vref. A source of the feedback transistor QF2 is coupled to a gate of the amplifying transistor QA via an inductor L1. A drain of the amplifying transistor QA is coupled to an inductor L2 to receive a voltage VD.

The bias compensation circuit 12 exploits a negative feedback mechanism, which is illustrated in the below. A current flowing through the transistor can be expressed as eq. 1, which is known in the art. When the turn on voltage Vto or the threshold voltage Vₜₕ decreases/increases (due to fabrication or temperature variation), a current ID1 flowing through the transistor Q (and also a current ID2 flowing through the amplifying transistor QA) would increase/decrease, a voltage VG1 at the gate of the feedback transistors QF1, QF2 would decrease/increase due to VG1=Vref−ID1*R1. A voltage VG at the source of the feedback transistor QF1 and a voltage VG2 at the source of the feedback transistor QF2 would decrease/increase, such that the current ID1 would decrease/increase. Therefore, the (biased) current ID2 may be maintained consistent. In another perspective, the bias compensation circuit 12 utilizes a negative feedback loop formed by the transistor Q and the feedback transistors QF1, QF2 to stabilize the biased current ID2.

$${I}_{D} = \frac{{μ}_{n} {C}_{o x}}{2} \frac{W}{L} {( {V}_{G S} - {V}_{h} )}^{2} \qquad ( eq . 1 )$$

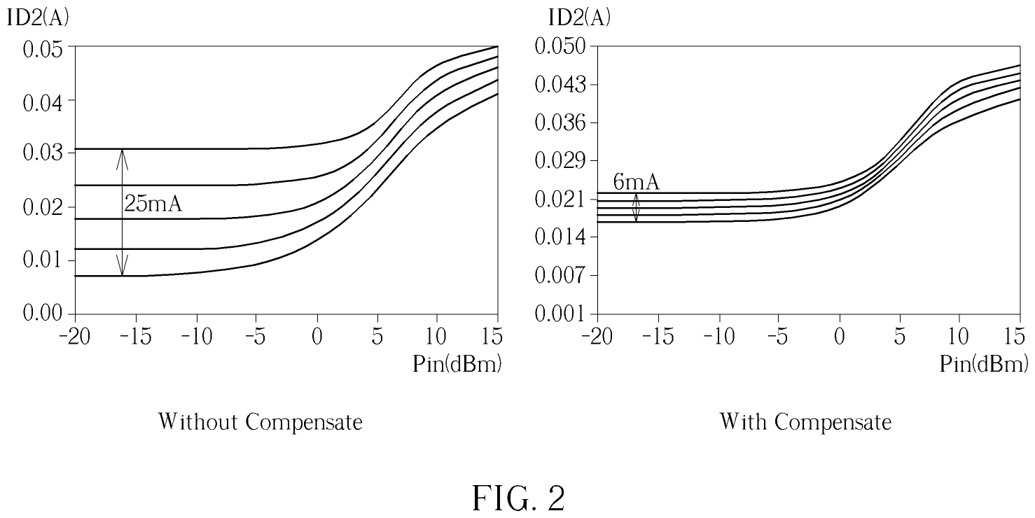

FIG. 2 represents results of the current ID2 flowing through the amplifying transistor QA under various turn on voltages Vto. The variation of the turn on voltages Vto lies between ±0.1V (volt). Different curves in FIG. 2 represent ID2 corresponding to different turn on voltages Vto. The left/right portion of FIG. 2 represent results of the current ID2 flowing through the amplifying transistor QA without/with the bias compensation circuit 12. The horizontal axis represents input power, denoted as Pin, of the amplifying transistor QA, and the vertical axis represents the current ID2. As can be seen from FIG. 2, when the input power Pin is low (e.g., less than −10 dBm), a variation of the current ID2 corresponding to the case without compensation is about 25 mA (milliampere). On the other hand, a variation of the current ID2 corresponding to the case with compensation, i.e., with the bias compensation circuit 12, is reduced to 6 mA. Therefore, the bias compensation circuit 12 is able to effectively reduce the current variation due to turn on voltage variation and stabilize the biased current ID2.

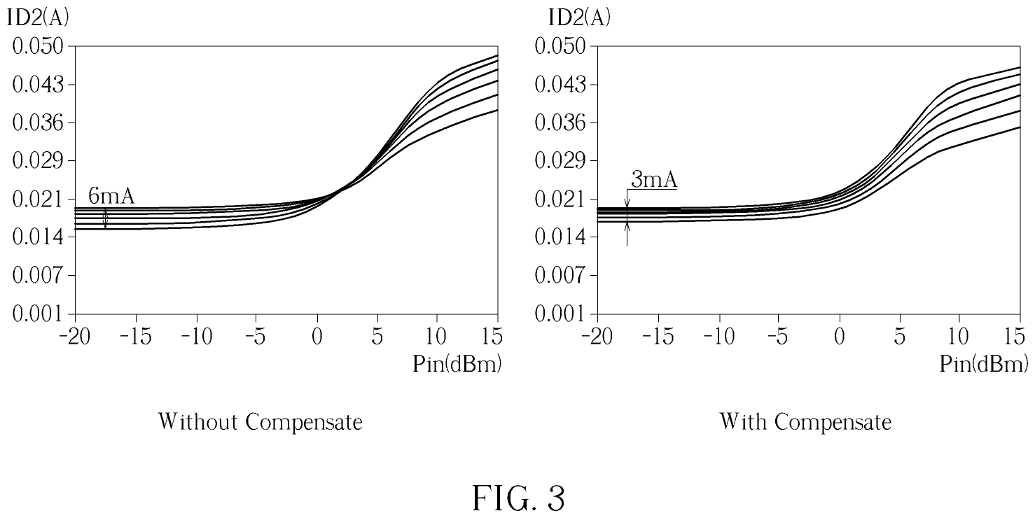

FIG. 3 represents results of the current ID2 flowing through the amplifying transistor QA under various temperatures. The variation of the temperatures lies between −30° C.-80° C. Different curves in FIG. 3 represent ID2 corresponding to different temperatures. The left/right portion of FIG. 3 represent results of the current ID2 flowing through the amplifying transistor QA without/with the bias compensation circuit 12. The horizontal axis represents input power, denoted as Pin, of the amplifying transistor QA, and the vertical axis represents the current ID2. As can be seen from FIG. 3, when the input power Pin is low (e.g., less than −10 dBm), a variation of the current ID2 corresponding to the case without compensation is about 6 mA. On the other hand, a variation of the current ID2 corresponding to the case with compensation, i.e., with the bias compensation circuit 12, is reduced to 3 mA. Therefore, the bias compensation circuit 12 is able to reduce the current variation due to temperature variation and stabilize the biased current ID2.

In a short remark, the bias compensation circuit 12 is able to reduce the current variation due to the turn on voltage variation and the temperature variation. Therefore, the bias compensation circuit 12 and the amplifying module 10 are able to provide a stable biased current, e.g., ID2.

Note that, the turn on voltage variation in unavoidable after a fabrication process. That is, fabricating a wafer (comprising a plurality of dies) may result in various turn on voltages corresponding to the plurality of dies. The bias compensation circuit 12 is suitable for a scenario that the turn on voltages of the transistors within one die are the same and the turn on voltages corresponding to different dies might be different, but not limited therein.

In summary, the bias compensation circuit of the present application utilizes the negative feedback loop to stabilize the biased current, such that the bias compensation circuit and the amplifying module are able to provide the stable biased current.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A bias compensation circuit, coupled to an amplifying circuit, the bias compensation circuit comprising:
a transistor, comprising a first terminal, a second terminal and a control terminal;
a first feedback transistor, comprising:
a control terminal, coupled to the first terminal of the transistor;
a first terminal, coupled to the control terminal of the transistor; and
a second terminal;
a second feedback transistor, comprising:
a control terminal, coupled to the first terminal of the transistor;
a first terminal, coupled to the amplifying circuit; and
a second terminal; and
a first resistor, comprising:
a first terminal, coupled to the first terminal of the transistor; and
a second terminal, configured to receive a first voltage.

2. The bias compensation circuit of claim 1, further comprising:
a second resistor, comprising:
a first terminal, coupled to the second terminal of the transistor; and
a second terminal, coupled to a ground.

3. The bias compensation circuit of claim 1, further comprising:
a third resistor, comprising:
a first terminal, coupled to the first terminal of the first feedback transistor; and
a second terminal, coupled to a ground.

4. The bias compensation circuit of claim 1, further comprising:
a fourth resistor, comprising:
a first terminal, coupled to the first terminal of the second feedback transistor; and
a second terminal, coupled to a ground.

5. The bias compensation circuit of claim 1, wherein the second terminal of the first feedback transistor and the second terminal of the second feedback transistor receive a second voltage.

6. The bias compensation circuit of claim 1, wherein the amplifying circuit comprises an amplifying transistor comprising a control terminal, and the first terminal of the second feedback transistor is coupled to the control terminal of the amplifying transistor.

7. The bias compensation circuit of claim 6, wherein the first terminal of the second feedback transistor is coupled to the control terminal of the amplifying transistor via an inductor.

8. An amplifying module, comprising:
an amplifying circuit; and
a bias compensation circuit, coupled to the amplifying circuit, the bias compensation circuit comprising:
a transistor, comprising a first terminal, a second terminal and a control terminal;
a first feedback transistor, comprising:
a control terminal, coupled to the first terminal of the transistor;
a first terminal, coupled to the control terminal of the transistor; and
a second terminal;
a second feedback transistor, comprising:
a control terminal, coupled to the first terminal of the transistor;
a first terminal, coupled to the amplifying circuit; and
a second terminal; and
a first resistor, comprising:
a first terminal, coupled to the first terminal of the transistor; and
a second terminal, configured to receive a first voltage.

9. The amplifying module of claim 8, further comprising:
a second resistor, comprising:
a first terminal, coupled to the second terminal of the transistor; and
a second terminal, coupled to a ground.

10. The amplifying module of claim 8, further comprising:
a third resistor, comprising:
a first terminal, coupled to the first terminal of the first feedback transistor; and
a second terminal, coupled to a ground.

11. The amplifying module of claim 8, further comprising:
a fourth resistor, comprising:
a first terminal, coupled to the first terminal of the second feedback transistor; and
a second terminal, coupled to a ground.

12. The amplifying module of claim 8, wherein the second terminal of the first feedback transistor and the second terminal of the second feedback transistor receive a second voltage.

13. The amplifying module of claim 8, wherein the amplifying circuit comprises an amplifying transistor comprising a control terminal, and the first terminal of the second feedback transistor is coupled to the control terminal of the amplifying transistor.

14. The amplifying module of claim 13, wherein the first terminal of the second feedback transistor is coupled to the control terminal of the amplifying transistor via an inductor.

15. The amplifying module of claim 8, wherein the amplifying module is formed within a die.

16. The amplifying module of claim 15, wherein the die is fabricated by a pHEMT (Pseudomorphic High Electron Mobility Transistor) process.
